(19) United States
(12) Patent Application Publication
(10) Pub. No.: US 2024/0355757 A1
(43) Pub. Date: Oct. 24, 2024

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Jeonghyun Kim, Suwon-si (KR); Sangjin Kim, Suwon-si (KR); Jaesuk Park, Suwon-si (KR); Yigwon Kim, Suwon-si (KR); Changmin Park, Suwon-si (KR); Hyungju Ryu, Suwon-si (KR)

(21) Appl. No.: 18/408,215

(22) Filed: Jan. 9, 2024

(30) Foreign Application Priority Data
Apr. 24, 2023 (KR) 10-2023-0053597

(51) Int. Cl. H01L 23/544

(52) U.S. Cl. CPC H01L 23/544; H01L 2223/54426

(57) ABSTRACT

The present disclosure relates to semiconductor devices and their fabrication methods. An example semiconductor device comprises a substrate including a logic cell region and a key region, a dummy active pattern on the key region, and a key pattern in the dummy active pattern. The key pattern includes a key cell that is recessed at an upper portion of the substrate. The key cell includes a bottom surface lower than a top surface of the dummy active pattern, and a plurality of inner lateral surfaces that surround the bottom surface. The inner lateral surfaces include a first inner lateral surface and a second inner lateral surface opposite to the first inner lateral surface. A ratio of a silicon atom surface density of the second inner lateral surface to a silicon atom surface density of the first inner lateral surface is in a range of about 0.9 to about 1.1.

### CROSS-REFERENCE TO RELATED APPLICATION

This application claims priority to Korean Patent Application No. 10-2023-0053597, filed on Apr. 24, 2023, in the Korean Intellectual Property Office, the disclosure of which is hereby incorporated by reference in its entirety.

### BACKGROUND

A semiconductor device having properties such as compactness, multi-functionality, and/or low manufacturing cost often is considered desirable in the electronics industry. Semiconductor devices may encompass semiconductor memory devices storing logic data, semiconductor logic devices processing operations of logic data, and hybrid semiconductor devices having both memory and logic elements. With the advanced development of the electronic industry, semiconductor devices increasingly require for high integration. For example, it is increasingly important for semiconductor to have high reliability, high speed, and/or multi-functionality. Semiconductor devices are gradually becoming more complicated and more integrated to meet these requested characteristics.

An increase in integration of semiconductor devices causes an increase in density of patterns formed on a substrate unit area. In addition, the number of layers formed on substrates increases due to multi-functionality and high performance of semiconductor devices. Therefore, it is sometimes useful to form patterns identifying exact positions during fabrication processes of semiconductor devices. Accordingly, alignment keys or overlay keys are used for alignment between layers stacked on substrates.

### SUMMARY

In certain aspects, the present disclosure relates to semiconductor devices with increased reliability, as well as methods of fabricating semiconductor devices with improved performance of alignment and overlay measurement.

In some implementations, a semiconductor device comprises: a substrate that includes including a logic cell region and a key region; a dummy active pattern on the key region; and a key pattern in the dummy active pattern. The key pattern may include a key cell that is recessed at an upper portion of the substrate. The key cell may include: a bottom surface lower than a top surface of the dummy active pattern; and a plurality of inner lateral surfaces that surround the bottom surface. The inner lateral surfaces may include a first inner lateral surface and a second inner lateral surface that are opposite to each other. A ratio of a silicon atom surface density of the second inner lateral surface to a silicon atom surface density of the first inner lateral surface may be in a range of about 0.9 to about 1.1.

In some implementations, a semiconductor device comprises: a substrate that includes a key region; a dummy active pattern on the key region; and a key pattern in the dummy active pattern. The key pattern may include a key cell that is recessed at an upper portion of the substrate. The key cell may include: a bottom surface lower than a top surface of the dummy active pattern; and a plurality of inner lateral surfaces that surround the bottom surface. The dummy active pattern may include a plurality of dummy active patterns arranged along a first direction. The plurality of dummy active patterns may extend along a second direction that intersects the first direction. The inner lateral surfaces may include first, second, and third inner lateral surfaces. The first inner lateral surface and the second inner lateral surface may be opposite to each other. The third inner lateral surface may connect the first inner lateral surface to the second inner lateral surface. Each of the first and second inner lateral surfaces may be parallel to a third direction that intersects all of the first direction and the second direction. The third inner lateral surface may be parallel to a fourth direction that is symmetric to the third direction about the first direction.

In some implementations, a semiconductor device comprises: a substrate that includes a key region; a dummy active pattern on the key region; and a key pattern in the dummy active pattern. The key pattern may include a plurality of key cells each of which is recessed at an upper portion of the substrate. The plurality of key cells may be arranged at a regular interval along the dummy active pattern. Each of the plurality of key cells may include: a bottom surface lower than a top surface of the dummy active pattern; and a plurality of inner lateral surfaces that surround the bottom surface. The plurality of key cells may have the same polygonal shape when viewed in plan.

In some implementations, a method of fabricating a semiconductor device comprises: forming a key pattern on a substrate that includes a logic cell region and a key region; using the key pattern as an alignment key to perform an ion implantation process on the logic cell region; forming a stack structure by alternately stacking a plurality of sacrificial layers and a plurality of active layers on the substrate; and using the key pattern as an alignment key to performing on the stack structure a patterning process to form an active pattern and a dummy active pattern on the logic cell region and the key region, respectively. The step of forming the key pattern may include recessing an upper portion of the substrate to form a key cell. When viewed in plan, the key cell may have a rhombic shape or a parallelogram shape.

### BRIEF DESCRIPTION OF THE DRAWINGS

FIG. 1 illustrates a plan view showing an example of a semiconductor device.

FIG. 2 illustrates a plan view of an example of a logic cell region depicted in FIG. 1.

FIGS. 3A, 3B, 3C, and 3D illustrate example cross-sectional views respectively taken along lines A-A′, B-B′, C-C′, and D-D′ of FIG. 2.

FIG. 4 illustrates a plan view of an example of a key region depicted in FIG. 1.

FIG. 5 illustrates an example of an enlarged plan view showing section M of FIG. 4.

FIGS. 6A, 6B, and 6C illustrate example cross-sectional views respectively taken along lines A-A′, B-B′, and C-C′ of FIG. 5.

FIGS. 7, 9, 11, and 13 illustrate plan views showing an example of a method of fabricating a semiconductor device.

FIGS. 8A, 10A, 12A, and 14A illustrate example cross-sectional views taken along line A-A′ of FIGS. 7, 9, 11, and 13, respectively.

FIGS. 8B, 10B, 12B, and 14B illustrate example cross-sectional views taken along line B-B′ of FIGS. 7, 9, 11, and 13, respectively.

FIG. 15 illustrates a plan view showing another example of a method of fabricating a semiconductor device.

FIG. 16 illustrates an example of a cross-sectional view taken along line A-A′ of FIG. 15.

FIGS. 17 and 18 illustrate plan views showing an example of a key cell.

### DETAILED DESCRIPTION

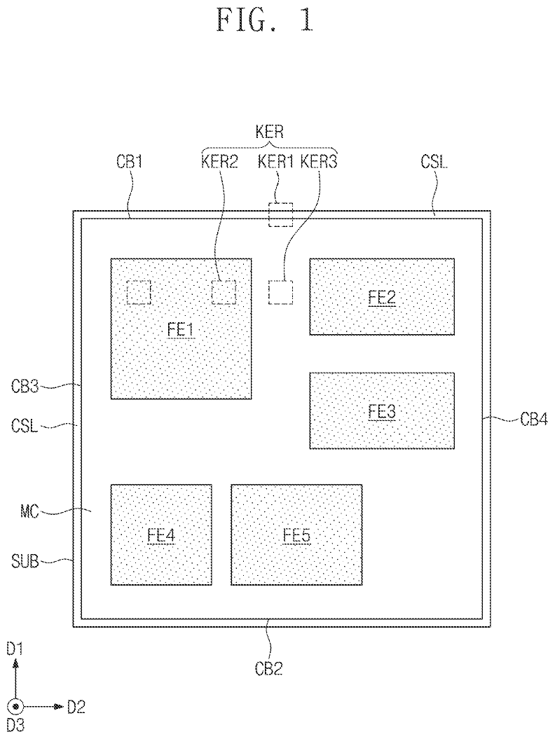

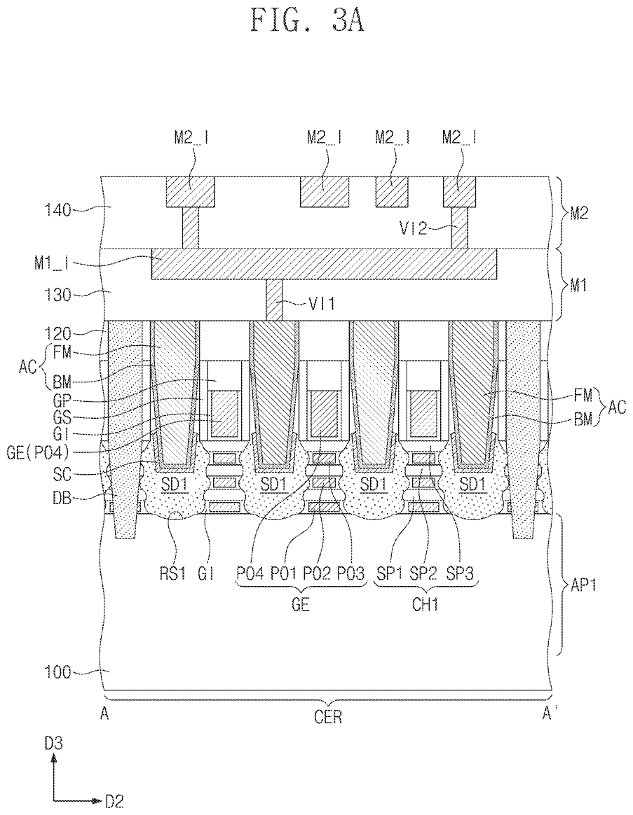

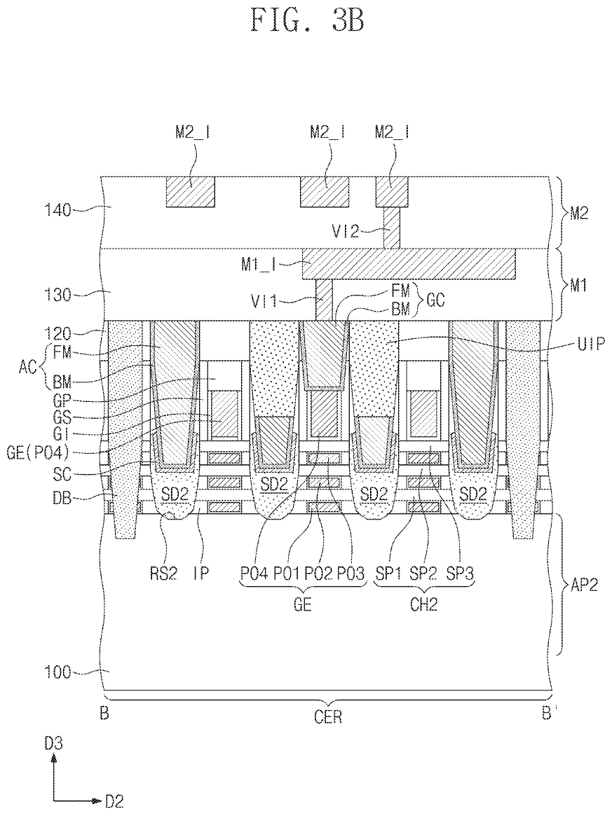

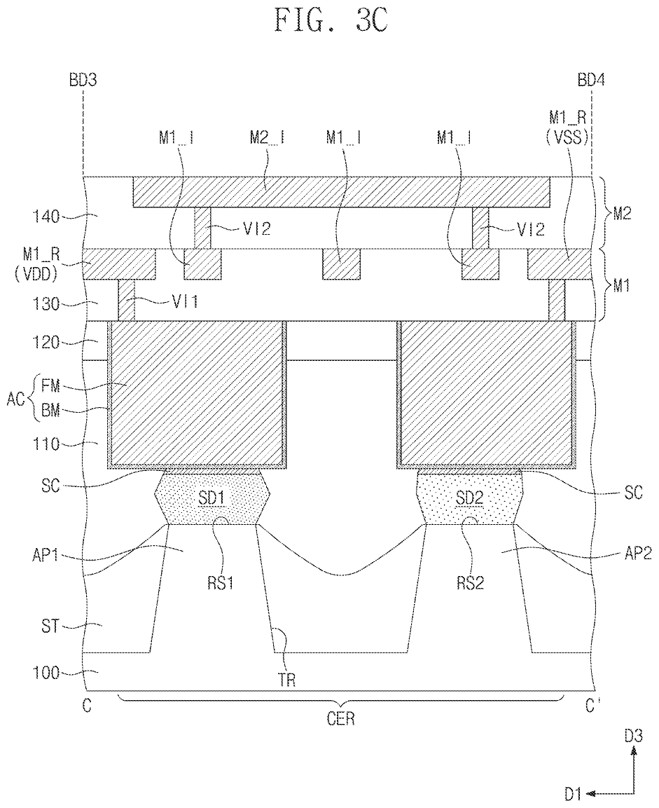

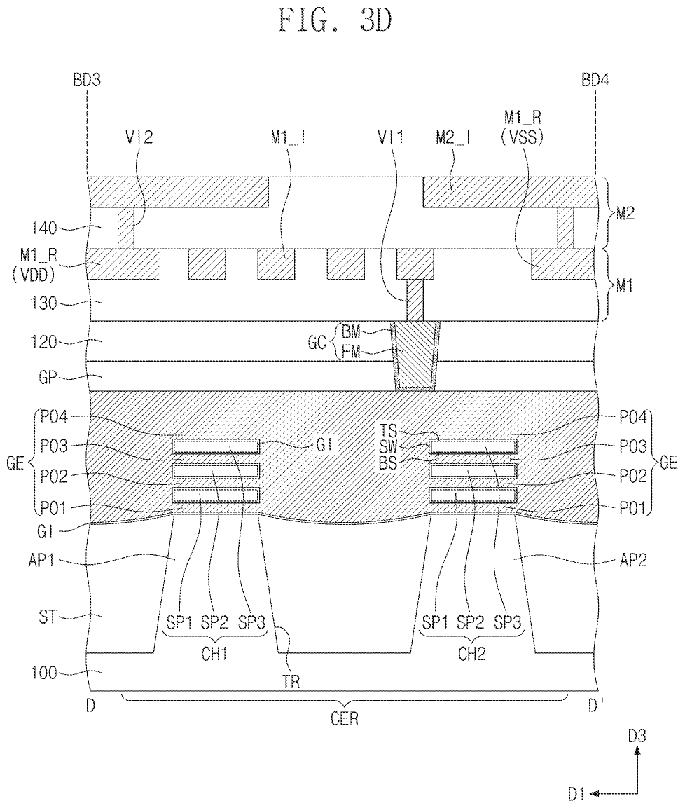

FIG. 1 illustrates a plan view showing an example of a semiconductor device. Referring to FIG. 1, a semiconductor device may include a main chip (MC) and a diced scribe line CSL that surrounds the MC. The MC may include first to fifth function elements FE1 to FE5 on a substrate (see 100 of FIGS. 3A to 3D). The substrate 100 may be a diced semiconductor substrate. The substrate 100 may support the first to fifth function elements FE1 to FE5.

The MC may include first to fourth boundaries CB1 to CB4. The first to fourth boundaries CB1 to CB4 may be defined between the diced scribe line CSL and the MC. The diced scribe line CSL may surround the first to fourth boundaries CB1 to CB4 of the MC. In an example, the diced scribe line CSL may include a first key region KER1 adjacent to the first boundary CB1 of the MC. For example, even after a wafer dicing process, the first key region KER1 may remain on the diced scribe line CSL.

Each of the first to fifth function elements FE1 to FE5 may be a function block included in an integrated circuit. Each of the first to fifth function elements FE1 to FE5 may include one of a memory block, an analog logic block, an input/output (I/O) logic block, a central processing unit (CPU) block, and a radio frequency block.

The first function element FE1 may include a logic cell region CER and a second key region KER2. For example, a key region KER may be provided not only a scribe line, but also on a function block. A third key region KER3 may be provided on a region between the first function element FE1 and the second function element FE2.

The key region KER may include the first, second, and third key regions KER1, KER2, and KER3 that are placed on different positions on the semiconductor device. At least one of the illustrated first, second, and third key regions KER1, KER2, and KER3 may be omitted in the semiconductor device or a semiconductor chip.

The key region KER may include key patterns which will be discussed below. The key pattern may include an overlay key, alignment key, or a combination thereof.

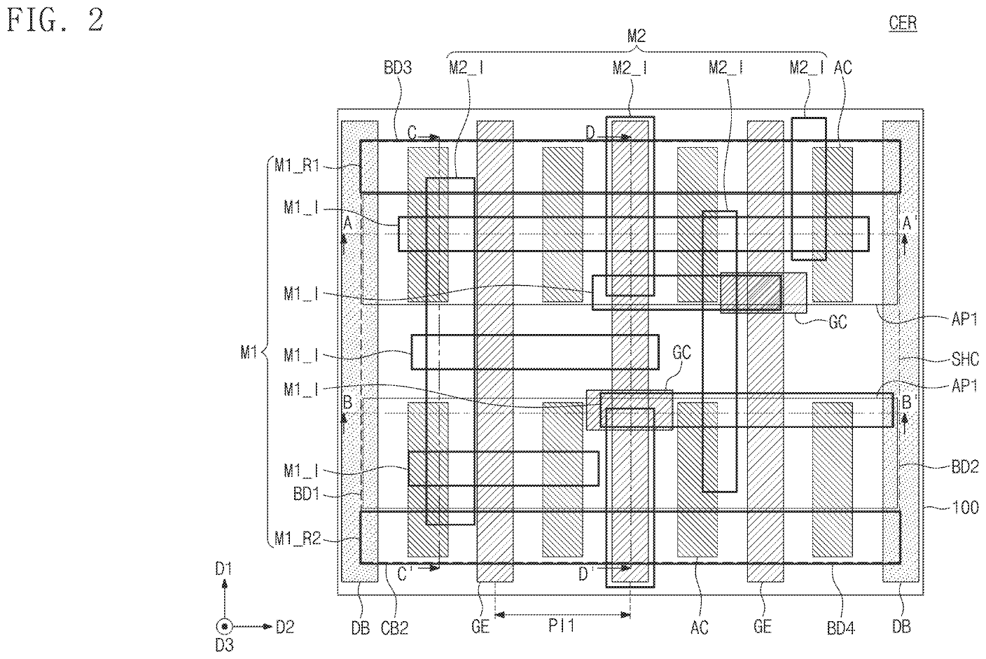

FIG. 2 illustrates a plan view of an example of a logic cell region depicted in in FIG. 1. FIGS. 3A, 3B, 3C, and 3D illustrate example cross-sectional views respectively taken along lines A-A′, B-B′, C-C′, and D-D′ of FIG. 2.

Referring to FIGS. 2 and 3A to 3D, a logic cell region CER may be included in the first function element FE1 of the semiconductor chip depicted in FIG. 1. The logic cell region CER may include a logic cell SHC that means a logic device, such as AND, OR, XOR, XNOR, and inverter, that performs a specific function. The logic cell SHC of the logic cell region CER may include transistors that constitute a logic device and may also include wiring lines that connect the transistors to each other. The substrate 100 may be a compound semiconductor substrate or a semiconductor substrate including silicon, germanium, or silicon-germanium. For example, the substrate 100 may be a silicon substrate.

The substrate 100 may include a first active pattern AP1 and a second active pattern AP2. Each of the first and second active patterns AP1 and AP2 may extend in a second direction D2. In an example, the first active pattern AP1 may be provided on a PMOSFET region, and the second active pattern AP2 may be provided on an NMOSFET region. The first active pattern AP1 and the second active pattern AP2 may be defined by a trench TR formed on an upper portion of the substrate 100. The first and second active patterns AP1 and AP2 may be vertically protruding portions of the substrate 100.

A device isolation layer ST may be provided on the substrate 100. The device isolation layer ST may fill the trench TR. The device isolation layer ST may include a silicon oxide layer. The device isolation layer ST may not cover any of first and second channel patterns CH1 and CH2 which will be discussed below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or a third direction D3).

The first, second, and third semiconductor patterns SP1, SP2, and SP3 may each be a nano-sheet. For example, each of the first and second channel patterns CH1 and CH2 may be a stack including stacked nano-sheets. Each of the first, second, and third semiconductor patterns SP1, SP2, and SP3 may include silicon (Si), germanium (Ge), or silicon-germanium (SiGe). For example, each of the first, second, and third semiconductor patterns SP1, SP2, and SP3 may include crystalline silicon.

A plurality of first source/drain patterns SD1 may be provided on the first active pattern AP1. A plurality of first recesses RS1 may be formed on an upper portion of the first active pattern AP1. The first source/drain patterns SD1 may be correspondingly provided in the first recesses RS1. The first source/drain patterns SD1 may be impurity regions having a first conductivity type (e.g., p-type). The first channel pattern CH1 may be interposed between a pair of first source/drain patterns SD1. For example, the pair of first source/drain patterns SD1 may be connected to each other through the stacked first, second, and third semiconductor patterns SP1, SP2, and SP3. In the implementations illustrated herein, the phrase source/drain pattern may be understood to mean a source terminal pattern or a drain terminal pattern of a transistor.

A plurality of second source/drain patterns SD2 may be provided on the second active pattern AP2. A plurality of second recesses RS2 may be formed on an upper portion of the second active pattern AP2. The second source/drain patterns SD2 may be correspondingly provided in the second recesses RS2. The second source/drain patterns SD2 may be impurity regions having a second conductivity type (e.g., n-type). The second channel pattern CH2 may be interposed between a pair of second source/drain patterns SD2. For example, the pair of second source/drain patterns SD2 may be connected to each other through the stacked first, second, and third semiconductor patterns SP1, SP2, and SP3.

The first and second source/drain patterns SD1 and SD2 may be epitaxial patterns formed by a selective epitaxial growth (SEG) process. For example, each of the first and second source/drain patterns SD1 and SD2 may have a top surface higher than that of the third semiconductor pattern SP3. For another example, at least one of the first and second source/drain patterns SD1 and SD2 may have a top surface at substantially the same level as that of a top surface of the third semiconductor pattern SP3.

In an example, the first source/drain patterns SD1 may include a semiconductor element (e.g., SiGe) whose lattice constant is greater than that of a semiconductor element of the substrate 100. Therefore, a pair of first source/drain patterns SD1 may provide the first channel pattern CH1 with compressive stress. The second source/drain patterns SD2 may include the same semiconductor element (e.g., Si) as that of the substrate 100.

In an example, the first source/drain pattern SD1 may have an uneven embossing shape on a sidewall thereof. For example, the sidewall of the first source/drain pattern SD1 may have a wavy profile. The sidewall of the first source/drain pattern SD1 may protrude toward each of first, second, and third inner electrodes PO1, PO2, and PO3 of a gate electrode (GE) which will be discussed below.

Gate electrodes GE may be provided to extend in a first direction D1, while running across the first and second channel patterns CH1 and CH2. The gate electrodes GE may be arranged at a first pitch in the second direction D2. Each of the gate electrodes GE may vertically overlap the first and second channel patterns CH1 and CH2.

The GE may include a first inner electrode PO1 interposed between the first semiconductor pattern SP1 and the active pattern AP1 or AP2, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

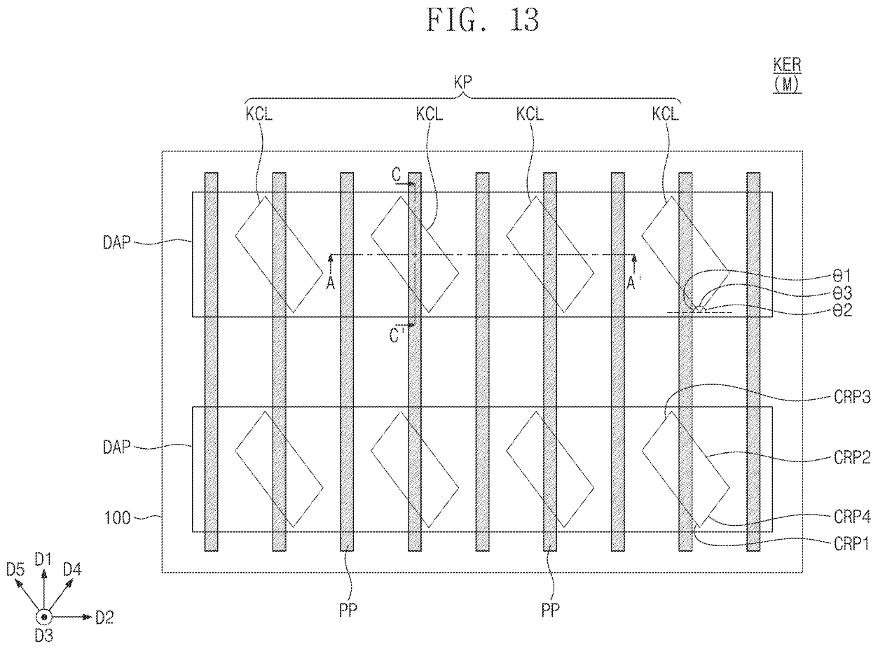

Referring to FIG. 13D, the GE may be provided on a top surface (TS), a bottom surface (BS), and opposite sidewalls SW of each of the first, second, and third semiconductor patterns SP1, SP2, and SP3. The GE may surround the TS, the BS, and the opposite sidewalls SW of each of the first, second, and third semiconductor patterns SP1, SP2, and SP3. For example, a transistor may be a three-dimensional field effect transistor (e.g., MBCFET or GAAFET) in which the GE three-dimensionally surrounds the first and second channel patterns CH1 and CH2.

Referring back to FIGS. 2 and 3A to 3D, a pair of gate spacers GS may be disposed on opposite sidewalls of the outer electrode PO4 of the GE. The gate spacers GS may extend in the first direction D1 along the GE. The gate spacers GS may have their top surfaces higher than that of the GE. The top surfaces of the gate spacers GS may be coplanar with that of a first interlayer dielectric layer 110 which will be discussed below. In an example, the gate spacers GS may include at least one selected from SiCN, SiCON, and SiN. In another example, the gate spacers GS may include a multiple layer formed of at least two selected from SiCN, SiCON, and SiN.

A gate capping pattern GP may be provided on the GE. The gate capping pattern GP may extend in the first direction D1 along the GE. The gate capping pattern GP may include a material having an etch selectivity with respect to first and second interlayer dielectric layers 110 and 120 which will be discussed below. For example, the gate capping pattern GP may include at least one selected from SiON, SiCN, SiCON, and SiN.

A gate dielectric layer GI may be interposed between the GE and the first channel pattern CH1 and between the GE and the second channel pattern CH2. The gate dielectric layer GI may cover the TS, the BS, and the opposite sidewalls SW of each of the first, second, and third semiconductor patterns SP1, SP2, and SP3. The gate dielectric layer GI may cover a top surface of the device isolation layer ST below the GE.

In an example, the gate dielectric layer GI may include an interfacial layer and a high-k dielectric layer. The interfacial layer may include a silicon oxide layer or a silicon oxynitride layer. The high-k dielectric layer may include a high-k dielectric material whose dielectric constant is greater than that of a silicon oxide layer. For example, the high-k dielectric layer may include at least one selected from hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

Referring back to FIG. 3D, inner spacers IP may be provided on the second active pattern AP2. The inner spacers IP may be correspondingly interposed between the second source/drain pattern SD2 and the first, second, and third inner electrodes PO1, PO2, and PO3 of the GE. The inner spacers IP may be in direct contact with the second source/drain pattern SD2. The inner spacer IP may separate the second source/drain pattern SD2 from each of the first, second, and third inner electrodes PO1, PO2, and PO3 of the GE.

Referring back to FIGS. 2 and 3A to 3D, the GE may include a first metal pattern and a second metal pattern on the first metal pattern. The first metal pattern may be provided on the gate dielectric layer GI and may be adjacent to the first, second, and third semiconductor patterns SP1, SP2, and SP3. The first metal pattern may include a work-function metal that controls a threshold voltage of a transistor. A thickness and composition of the first metal pattern may be adjusted to achieve a desired threshold voltage of a transistor. For example, the first, second, and third inner electrodes PO1, PO2, and PO3 of the GE may be formed of the first metal pattern or the work-function metal.

The first metal pattern may include a metal nitride layer. For example, the first metal pattern may include nitrogen (N) and at least one metal selected from titanium (Ti), tantalum (Ta), aluminum (Al), tungsten (W), and molybdenum (Mo). In addition, the first metal pattern may further include carbon (C). The first metal pattern may include a plurality of stacked work-function metal layers.

The second metal pattern may include metal whose resistance is less than that of the first metal pattern. For example, the second metal pattern may include at least one metal selected from tungsten (W), aluminum (Al), titanium (Ti), and tantalum (Ta). The outer electrode PO4 of the GE may include a first metal pattern and a second metal pattern on the first metal pattern.

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with that of the gate capping pattern GP and that of the gate spacer GS.

The first interlayer dielectric layer 110 may be provided thereon with a second interlayer dielectric layer 120 that covers the gate capping pattern GP. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

The logic cell SHC may have a first boundary BD1 and a second boundary BD2 that are opposite to each other in the second direction D2. The first and second boundaries BD1 and BD2 may extend in the first direction D1. The logic cell SHC may have a third boundary BD3 and a fourth boundary BD4 that are opposite to each other in the first direction D1. The third and fourth boundaries BD3 and BD4 may extend in the second direction D2.

The logic cell SHC may be provided on its opposite sides with a pair of separation structures DB that are opposite to each other in the second direction D2. For example, the pair of separation structures DB may be provided on the first and second boundaries BD1 and BD2 of the logic cell SHC. The separation structure DB may extend in the first direction D1 parallel to the gate electrodes GE. A pitch between the separation structure DB and its adjacent GE may be substantially the same as the first pitch.

The separation structure DB may penetrate the gate capping pattern GP and the GE to extend into the active pattern AP1 or AP2. The separation structure DB may penetrate an upper portion of each of the first and second active patterns AP1 and AP2. The separation structure DB may electrically separate an active region of the logic cell SHC from an active region of another cell.

Active contacts AC may be provided to penetrate the first and second interlayer dielectric layers 110 and 120 to come into electrical connection with the first and second source/drain patterns SD1 and SD2. A pair of active contacts AC may be correspondingly provided on opposite sides of the GE. When viewed in plan, the active contact AC may have a bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. Although not shown, the active contact AC may cover a portion of the top surface of the gate capping pattern GP.

The active contacts AC may be arranged at the first pitch in the second direction D2. For example, a pitch between the active contacts AC may be substantially the same as the first pitch between the gate electrodes GE.

A metal-semiconductor compound layer SC, such as a silicide layer, may be interposed between the active contact AC and the first source/drain pattern SD1 and between the active contact AC and the second source/drain pattern SD2. The active contact AC may be electrically connected through the metal-semiconductor compound layer SC to one of the first and second source/drain patterns SD1 and SD2. For example, the metal-semiconductor compound layer SC may include at least one selected from titanium silicide, tantalum silicide, tungsten silicide, nickel silicide, and cobalt silicide.

Gate contacts GC may be provided to penetrate the second interlayer dielectric layer 120 and the gate capping pattern GP to come into electrical connection with the gate electrodes GE. When viewed in plan, the gate contacts GC may be disposed to overlap the first active pattern AP1 and the second active pattern AP2. For example, the gate contact GC may be provided on the second active pattern AP2 (see FIG. 3B).

In an example, referring to FIG. 3B, the active contact AC may have an upper portion adjacent to the gate contact GC, and an upper dielectric pattern UIP may fill the upper portion of the active contact AC. The upper dielectric pattern UIP may have a bottom surface lower than that of the gate contact GC. For example, the upper dielectric pattern UIP may cause the active contact AC adjacent to the gate contact GC to have a top surface lower than the bottom surface of the gate contact GC. Therefore, it may be possible to prevent a short-circuit resulting from contact between the gate contact GC and its adjacent active contact AC.

Each of the active contact AC and the gate contact GC may include a conductive pattern FM and a barrier pattern BM that surrounds the conductive pattern FM. For example, the conductive pattern FM may include at least one metal selected from aluminum, copper, tungsten, molybdenum, and cobalt. The barrier pattern BM may cover sidewalls and a bottom surface of the conductive pattern FM. The barrier pattern BM may include a metal layer and a metal nitride layer.

The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CON) layer, and a platinum nitride (PtN) layer.

A first metal layer M1 may be provided in the third interlayer dielectric layer 130. For example, the first metal layer M1 may include a first power line M1_R1, a second power line M1_R2, and first wiring lines M1_I. The lines M1_R1, M1_R2, and M1_I of the first metal layer M1 may parallel extend in the second direction D2.

For example, the first and second power lines M1_R1 and M1_R2 may be respectively provided on the third and fourth boundaries BD3 and BD4 of the logic cell SHC. The first power line M1_R1 may extend in the second direction D2 along the third boundary BD3. The second power line M1_R2 may extend in the second direction D2 along the fourth boundary BD4.

The first wiring lines M1_I of the first metal layer M1 may be disposed between the first and second power lines M1_R1 and M1_R2. The first wiring lines M1_I of the first metal layer M1 may be arranged at a second pitch along the first direction D1. For example, the second pitch between the first wiring lines M1_I may be less than the first pitch. Each of the first wiring lines M1_I may have a line-width less than that of each of the first and second power lines M1_R1 and M1_R2.

The first metal layer M1 may further include first vias VI1. The first vias VI1 may be correspondingly provided below the lines M1_R1, M1_R2, and M1_I of the first metal layer M1. The first via VI1 may electrically connect the active contact AC to a wiring line of the first metal layer M1. The first via VI1 may electrically connect the gate contact GC to a wiring line of the first metal layer M1.

A certain line and its underlying first via VI1 of the first metal layer M1 may be formed by individual processes. For example, the certain line and its underlying first via VI1 of the first metal layer M1 may each be formed by a single damascene process. A sub-20 nm process may be employed to fabricate a semiconductor device.

A second metal layer M2 may be provided in the fourth interlayer dielectric layer 140. The second metal layer M2 may include a plurality of second wiring lines M2_I. The second wiring lines M2_I of the second metal layer M2 may each have a linear or bar shape that extends in the first direction D1. For example, the second wiring lines M2_I may parallel extend in the first direction D1.

The second metal layer M2 may further include second vias VI2 that are correspondingly provided below the second wiring lines M2_I. A certain line of the first metal layer M1 may be electrically through the second via VI2 to a corresponding line of the second metal layer M2. For example, a wiring line and its underlying second via VI2 of the second metal layer M2 may be simultaneously formed in a dual damascene process.

The first and second metal layers M1 and M2 may have their wiring lines that include the same or different conductive materials. For example, the wiring lines of the first and second metal layers M1 and M2 may include at least one metallic material selected from aluminum, copper, tungsten, molybdenum, ruthenium, and cobalt. Although not shown, other metal layers (e.g., M3, M4, M5, etc.) may be additionally stacked on the fourth interlayer dielectric layer 140. Each of the stacked metal layers may include wiring lines for routing between cells.

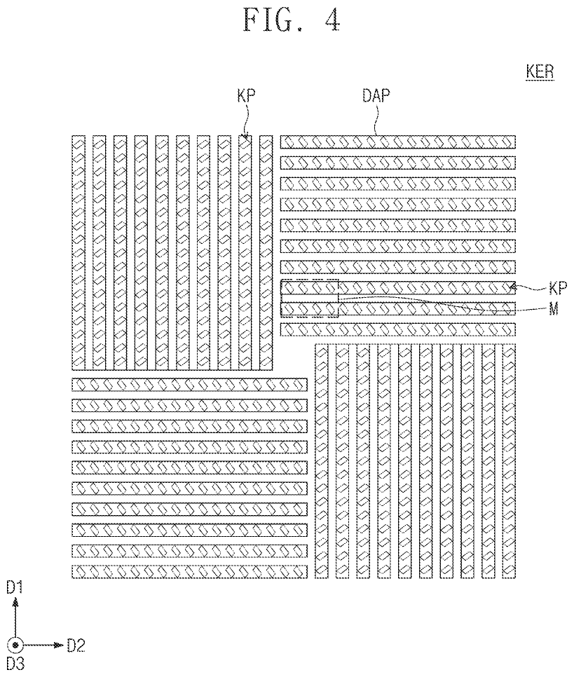

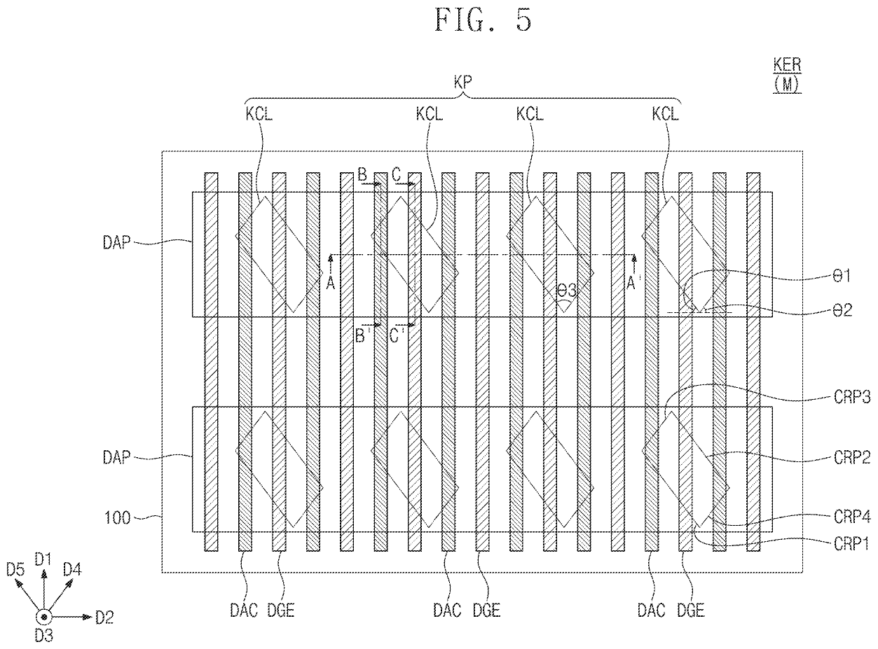

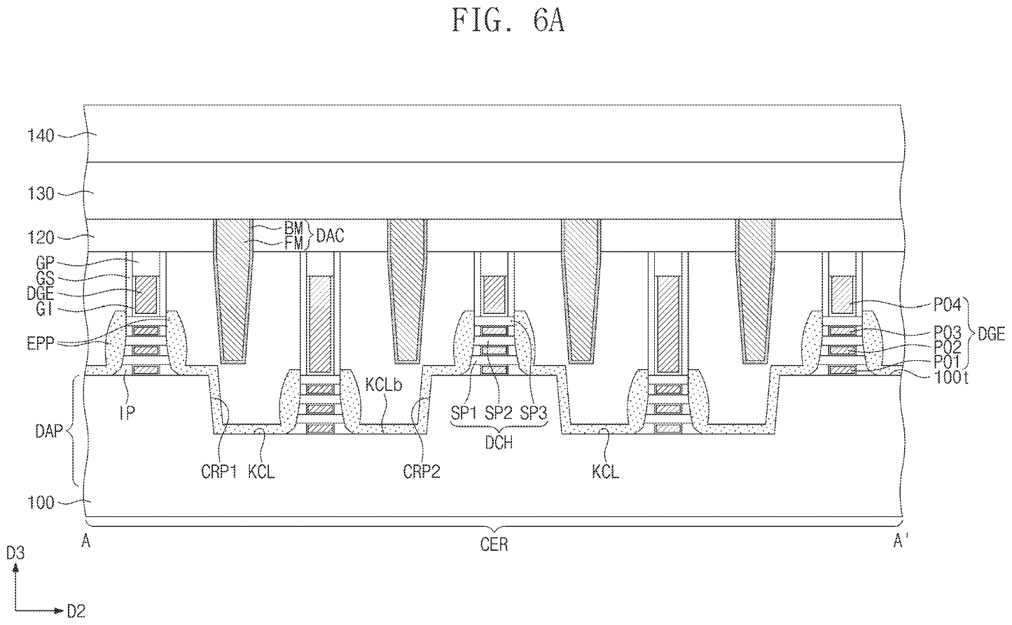

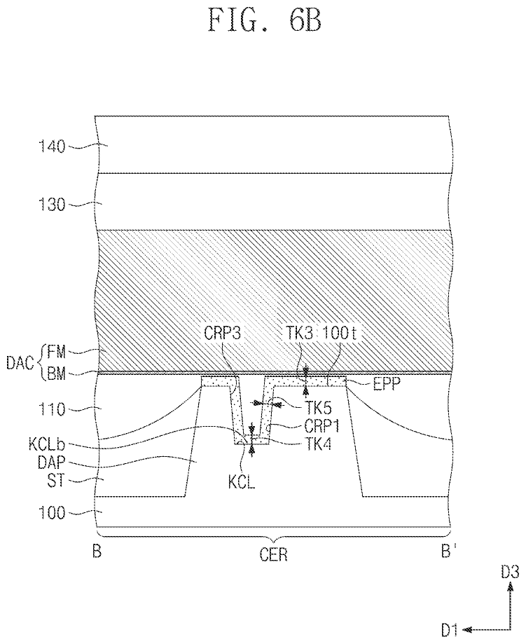

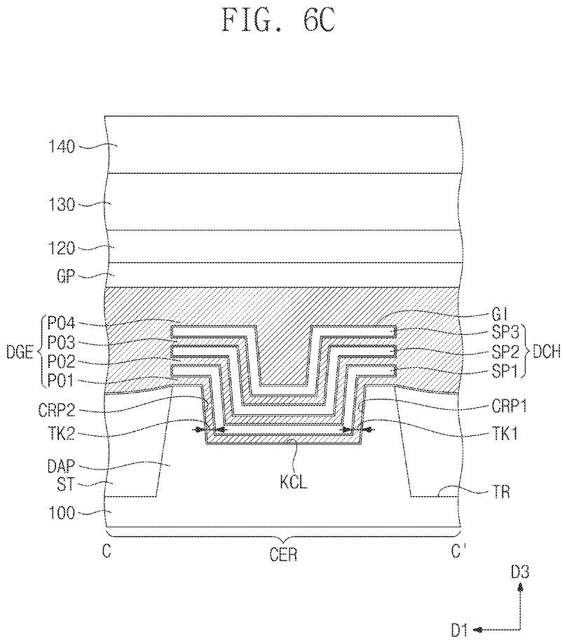

FIG. 4 illustrates a plan view of an example of a key region depicted in FIG. 1. FIG. 5 illustrates an example of an enlarged plan view showing section M of FIG. 4. FIGS. 6A, 6B, and 6C illustrate example cross-sectional views respectively taken along lines A-A′, B-B′, and C-C′ of FIG. 5.

Referring to FIG. 4, it is illustrated one key region KER of the first, second, and third key regions KER1, KER2, and KER3 in the semiconductor chip depicted in FIG. 1. For example, the key region KER of FIG. 4 may indicate the first key region KER1 in the diced scribe line CSL depicted in FIG. 1.

The key region KER may include key patterns KP used in fabrication process for the semiconductor chip. The key patterns KP may include an overlay key, alignment key, or a combination thereof. One of the key patterns KP may extend in the first direction D1. Another of the key patterns KP may extend in the second direction D2.

Dummy active patterns DAP may be correspondingly provided on the key patterns KP. One of the dummy active patterns DAP may extend in the first direction D1. Another of the dummy active patterns DAP may extend in the second direction D2.

The key pattern KP according to some implementations may be used as an alignment key for performing an ion implantation process on the substrate 100 of the logic cell region CER. In addition, the key pattern KP may be used as an overlay key of a photolithography process for forming the first and second active patterns AP1 and AP2.

Referring to FIG. 5, the key pattern KP may include a plurality of key cells KCL. In an example, the key pattern KP that extends in the second direction D2 may include a plurality of key cells KCL arranged at a third pitch along the second direction D2. In an example, the third pitch between the key cells KCL may be greater than the first pitch between the gate electrodes GE discussed above. The third pitch may be about 1.5 times to about 10 times the second pitch.

The key cells KCL may have the same planar shape. When viewed in plan, each of the key cells KCL may have a polygonal shape. For example, the shape of the key cell KCL may have a rhombic shape or a parallelogram shape.

The key cell KCL may have at least four inner lateral surfaces CRP1 to CRP4. The inner lateral surfaces of the key cell KCL may include a first crystal plane CRP1, a second crystal plane CRP2, a third crystal plane CRP3, and a fourth crystal plane CRP4. The first crystal plane CRP1 and the second crystal plane CRP2 may be parallel to each other in a fifth direction D5. The third crystal plane CRP3 and the fourth crystal plane CRP4 may be parallel to each other in a fourth direction D4.

The fourth direction D4 according to some implementations may intersect all of the first direction D1 and the second direction D2. The fifth direction D5 according to some implementations may intersect all of the first direction D1 and the second direction D2. The fourth direction D4 and the fifth direction D5 may be symmetric about the first direction D1.

In an example, when viewed in plan, the first crystal plane CRP1 may have a first angle θ1 with respect to the second direction D2. When viewed in plan, the fourth crystal plane CRP4 may have a second angle θ2 with respect to the second direction D2. The first angle θ1 and the second angle θ2 may be substantially the same as each other. Each of the first angle θ1 and the second angle θ2 may range from about 10° to about 80°.

The first crystal plane CRP1 and the fourth crystal plane CRP4 may be adjacent to each other. The first crystal plane CRP1 and the fourth crystal plane CRP4 may meet to define a corner of the key cell KCL. The first crystal plane CRP1 and the fourth crystal plane CRP4 may meet to form a third angle θ3. The third angle θ3 may have an acute angle less than about 90°. For example, the third angle θ3 may range from about 10° to about 80°.

Referring to FIGS. 5 and 6A to 6C, a plurality of key cells KCL may be provided on an upper portion of the substrate 100 of the key region KER. Each of the key cells KCL may be a recess, hole, or trench formed on an upper portion of the substrate 100. The key cell KCL may have a crater shape that is recessed from a top surface 100t of the substrate 100.

The key cell KCL may include the aforementioned four inner lateral surfaces, or the first to fourth crystal planes CRP1 to CRP4. The key cell KCL may further include a bottom surface KCLb surrounded by the first to fourth crystal planes CRP1 to CRP4. The bottom surface KCLb of the key cell KCL may be lower than the top surface 100t of the substrate 100. In an example, the bottom surface KCLb of the key cell KCL may be lower than the top surface of the device isolation layer ST.

The substrate 100 according to some implementations may be a monocrystalline silicon wafer. The substrate 100 may be a (100) wafer, a (110) wafer, or a (111) wafer. For example, the substrate 100 may be a (110) wafer or a (111) wafer.

Each of the first to fourth crystal planes CRP1 to CRP4 of the key cell KCL may be a silicon crystal plane having certain Miller indices. In an example, the first to fourth crystal planes CRP1 to CRP4 may be of the same family of crystal planes. The first to fourth crystal planes CRP1 to CRP4 may be a {a b c} plane. The Miller indices of a, b, and c may each be an integer between 0 and 5.

In some implementations, the first to fourth crystal planes CRP1 to CRP4 may have substantially the same silicon atom surface density. The silicon atom surface density may mean the number per unit area of silicon atoms arranged on a crystal plane.

For example, the first to fourth crystal planes CRP1 to CRP4 may be a {112} plane, and the silicon atom surface density of each of the first to fourth crystal planes CRP1 to CRP4 may be about 5.54×10¹⁴/cm². For another example, the first to fourth crystal planes CRP1 to CRP4 may be a {110} plane, and the silicon atom surface density of each of the first to fourth crystal planes CRP1 to CRP4 may be about 9.6×10¹⁴/cm². For another example, the first to fourth crystal planes CRP1 to CRP4 may be a {100} plane, and the silicon atom surface density of each of the first to fourth crystal planes CRP1 to CRP4 may be about 6.8×10¹⁴/cm². As such, the silicon atom surface density may be changed depending on which Miller indices the silicon crystal plane has.

In some implementations, a value of about 0.9 to about 1.1 may be given as a ratio of the silicon atom surface density of the second crystal plane CRP2 to the silicon atom surface density of the first crystal plane CRP1. For example, as discussed above, the silicon atom surface density of the first crystal plane CRP1 may be substantially the same as that of the second crystal plane CRP2.

A value of about 0.9 to about 1.1 may be given as a ratio of the silicon atom surface density of the third crystal plane CRP3 to the silicon atom surface density of the first crystal plane CRP1. A value of about 0.9 to about 1.1 may be given as a ratio of the silicon atom surface density of the fourth crystal plane CRP4 to the silicon atom surface density of the third crystal plane CRP3.

When the first to fourth crystal planes CRP1 to CRP4 have substantially the same silicon atom surface density, the first to fourth crystal planes CRP1 to CRP4 may have substantially the same growth rate. For example, when a selective epitaxial growth (SEG) process is used to grow a semiconductor layer on the first to fourth crystal planes CRP1 to CRP4, the semiconductor layer may have substantially the same growth rate on the first to fourth crystal planes CRP1 to CRP4. The semiconductor layer may include silicon (Si), germanium (Ge), or silicon-germanium (SiGe).

The key cell KCL according to some implementations may be constituted by the first to fourth crystal planes CRP1 to CRP4 having substantially the same silicon atom surface density. Thus, as discussed below, a subsequently described stack structure STL may be stably formed to have a constant thickness on the key cell KCL. Accordingly, keys having a uniform size may be provided to prevent process failure and to increase reliability of the semiconductor device.

A plurality of dummy active patterns DAP may be provided on the key region KER of the substrate 100. The dummy active patterns DAP may be arranged along the first direction D1. The dummy active patterns DAP may extend in the second direction D2.

Each of the dummy active patterns DAP may be provided on the key pattern KP. The dummy active pattern DAP may overlap the key pattern KP. For example, the dummy active pattern DAP may overlap a plurality of key cells KCL arranged along the second direction D2.

The dummy active patterns DAP may be simultaneously formed with the first and second active patterns AP1 and AP2 on the logic cell region CER discussed above. A device isolation layer ST may be provided to fill a trench TR between the dummy active patterns DAP.

A dummy channel pattern DCH may be provided on the dummy active pattern DAP. The dummy channel pattern DCH may include a first semiconductor pattern SP1, a second semiconductor pattern SP2, and a third semiconductor pattern SP3 that are sequentially stacked. The first, second, and third semiconductor patterns SP1, SP2, and SP3 may be spaced apart from each other in a vertical direction (or the third direction D3). The first, second, and third semiconductor patterns SP1, SP2, and SP3 may each be a nano-sheet. For example, the dummy channel pattern DCH may be a stack including stacked nano-sheets. The dummy channel pattern DCH may be simultaneously formed with the first and second channel patterns CH1 and CH2 on the logic cell region CER discussed above.

At least one of the dummy channel patterns DCH may be provided on the key cell KCL. The at least one dummy channel pattern DCH may be provided on the bottom surface KCLb of the key cell KCL. Therefore, the dummy channel pattern DCH on the bottom surface KCLb of the key cell KCL may be located at a lower level than that of the dummy channel pattern DCH on the top surface 100t of the substrate 100 (see FIG. 6A).

The first crystal plane CRP1 of the key cell KCL may be positioned between neighboring dummy channel patterns DCH. The second crystal plane CRP2 of the key cell KCL may be positioned between neighboring dummy channel patterns DCH.

An epitaxial pattern EPP may be provided on a sidewall of each of the dummy channel patterns DCH. In an example, the epitaxial pattern EPP may extend from one dummy channel pattern DCH to its adjacent another dummy channel pattern DCH. The epitaxial pattern EPP may cover the crystal planes CRP1 to CRP4 and the bottom surface KCLb of the key cell KCL. For example, the epitaxial pattern EPP may be simultaneously formed with the second source/drain pattern SD2 on the logic cell region CER discussed above. The epitaxial pattern EPP may include a silicon epitaxial pattern.

In an example, referring to FIG. 6B, the key cell KCL may be formed offset in the first direction D1 from a center of the dummy active pattern DAP. The epitaxial pattern EPP may cover the top surface 100t of the substrate 100. The epitaxial pattern EPP may cover the inner lateral surfaces CRP1 to CRP4 and the bottom surface KCLb of the key cell KCL. The epitaxial pattern EPP may have a uniform thickness.

In some implementations, a thickness TK5 of the epitaxial pattern EPP on each of the crystal planes CRP1 to CRP4 of the key cell KCL may be different from a thickness TK3 of the epitaxial pattern EPP on the top surface 100t of the substrate 100. The thickness TK3 of the epitaxial pattern EPP on the top surface 100t of the substrate 100 may be substantially the same as a thickness TK4 of the epitaxial pattern EPP on the bottom surface KCLb of the key cell KCL. This may be caused by the fact that the silicon atom surface density of the top surface 100t of the substrate 100 is substantially the same as that of the bottom surface KCLb of the key cell KCL, but is different from that of each of the crystal planes CRP1 to CRP4 of the key cell KCL.

Dummy gate electrodes (DGEs) may be provided to run across the dummy active patterns DAP and to extend in the first direction D1. The DGEs may be simultaneously formed with the gate electrodes GE on the logic cell region CER discussed above. For example, a description of the DGE may be the same as that of the GE on the logic cell region CER discussed above.

In an example, the dummy gate electrodes DGE may be arranged at a fourth pitch in the second direction D2. The fourth pitch may be greater than the first pitch between the gate electrodes GE. In an example, a line-width in the second direction D2 of the DGE may be the same as or greater than that of the GE on the logic cell region CER.

The DGE may include a first inner electrode PO1 interposed between the dummy active pattern DAP and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 6C, at least one DGE may be provided on the key cell KCL. The first to third semiconductor patterns SP1 to SP3 may be provided between the DGE and the key cell KCL. Each of the first to third semiconductor patterns SP1 to SP3 may have a bending shape that corresponds to a profile of the key cell KCL. For example, each of the first to third semiconductor patterns SP1 to SP3 may have a U shape.

Each of the first to third inner electrodes PO1 to PO3 on the key cell KCL may also have a bending shape that corresponds to the profile of the key cell KCL. For example, each of the first to third inner electrodes PO1 to PO3 may have a U shape.

In some implementations, the first inner electrode PO1 on the first crystal plane CRP1 may have a first thickness TK1. The first inner electrode PO1 on the second crystal plane CRP2 may have a second thickness TK2. The first thickness TK1 and the second thickness TK2 may be substantially the same as each other. This may be caused by the fact that a semiconductor layer on the first crystal plane CRP1 is substantially the same as that of a semiconductor layer on the second crystal plane CRP2. Likewise, a thickness of the first semiconductor pattern SP1 on the first crystal plane CRP1 may be substantially the same as that of the first semiconductor pattern SP1 on the second crystal plane CRP2.

The DGE may be provided on a top surface, a bottom surface, and opposite sidewalls of each of the first, second, and third semiconductor patterns SP1, SP2, and SP3. The DGE may surround the first to third semiconductor patterns SP1 to SP3.

Referring back to FIGS. 5 and 6A to 6C, a pair of gate spacers GS may be disposed on opposite sidewalls of the outer electrode PO4 of the DGE. A description of the gate spacers GS may be the same as that of the gate spacers GS on the logic cell region CER discussed above.

A gate capping pattern GP may be provided on the DGE. A description of the gate capping pattern GP may be the same as that of the gate capping pattern GP on the logic cell region CER discussed above.

A gate dielectric layer GI may be interposed between the dummy gat electrode DGE and the dummy channel pattern DCH. The gate dielectric layer GI may cover the top surface, the bottom surface, and the opposite sidewalls of each of the first, second, and third semiconductor patterns SP1, SP2, and SP3. A description of the gate dielectric layer GI may be the same as that of the gate dielectric layer GI on the logic cell region CER discussed above.

The substrate 100 may have first to fourth interlayer dielectric layers 110 to 140 provided on the key region KER. A description of the first to fourth interlayer dielectric layers 110 to 140 may be the same as that of the first to fourth interlayer dielectric layers 110 to 140 on the logic cell region CER discussed above.

Dummy active contacts DAC may be provided to penetrate the first and second interlayer dielectric layers 110 and 120 to extend toward the substrate 100. Each of the dummy active contacts DAC may include a conductive pattern FM and a barrier pattern BM that surrounds the conductive pattern FM. The dummy active contacts DAC may be simultaneously formed with the active contacts AC on the logic cell region CER discussed above. For example, a description of the dummy active contact DAC may be the same as that of the active contact AC on the logic cell region CER discussed above.

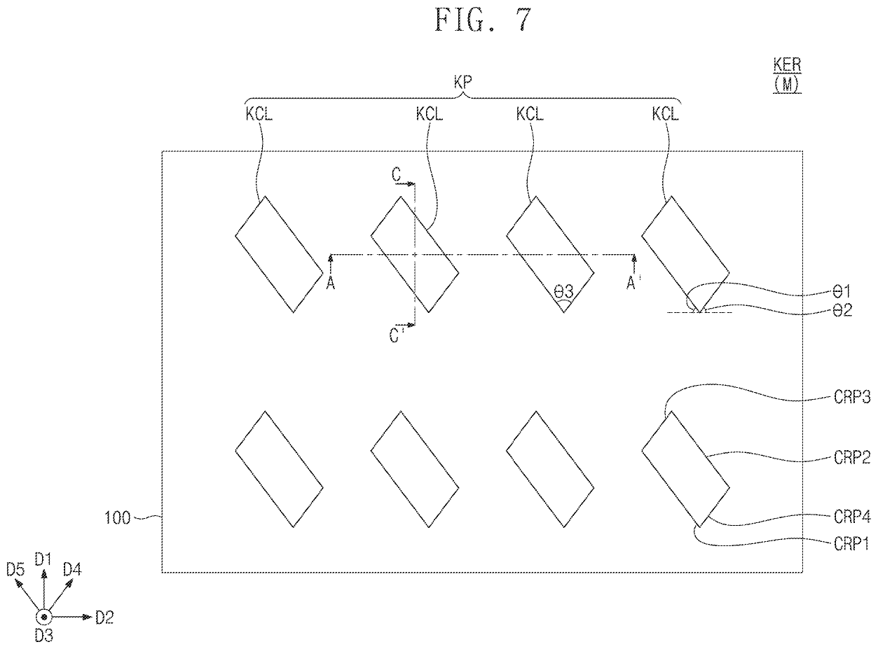

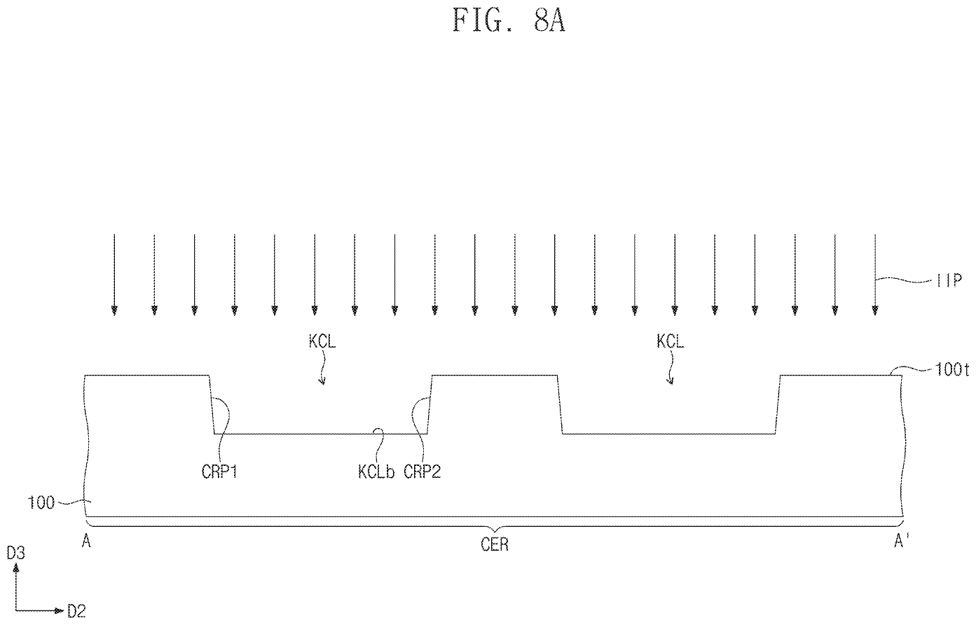

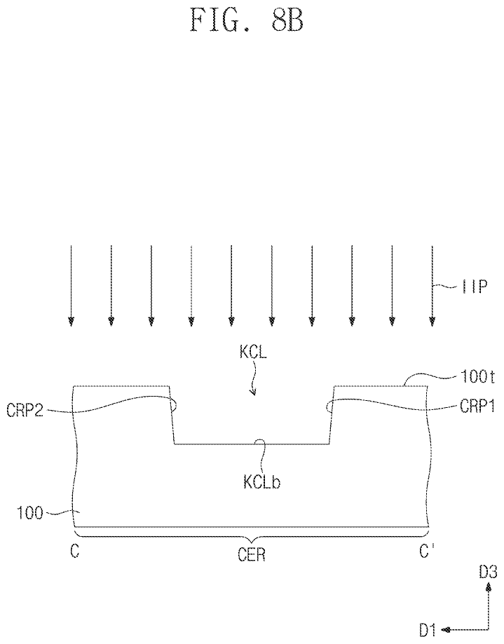

FIGS. 7, 9, 11, and 13 illustrate plan views showing an example of a method of fabricating a semiconductor device. FIGS. 8A, 10A, 12A, and 14A illustrate example cross-sectional views taken along line A-A′ of FIGS. 7, 9, 11, and 13, respectively. FIGS. 8B, 10B, 12B, and 14B illustrate example cross-sectional views taken along line B-B′ of FIGS. 7, 9, 11, and 13, respectively.

Referring to FIGS. 7, 8a, and 8B, a substrate 100 may be provided which includes a key region KER. The substrate 100 may be a monocrystalline silicon wafer. For example, the substrate 100 may be a (100) wafer, a (110) wafer, or a (111) wafer. Preferably, the substrate 100 may be a (110) wafer or a (111) wafer.

Key patterns KP may be formed on the key region KER. Each of the key patterns KP may include a plurality of key cells KCL arranged in a second direction D2. The formation of the key cells KCL may include using a photolithography process to etch an upper portion of the substrate 100.

Each of the key cells KCL may be patterned to have first to fourth crystal planes CRP1 to CRP4. When viewed in plan, the first crystal plane CRP1 and the second crystal plane CRP2 may be formed parallel to a fifth direction D5. When viewed in plan, the third crystal plane CRP3 and the fourth crystal plane CRP4 may be formed parallel to a fourth direction D4.

The fifth direction D5 may have a first angle θ1 with respect to the second direction D2, and the fourth direction D4 may have a second angle θ2 with respect to the second direction D2. The first angle θ1 and the second angle θ2 may be substantially the same as each other. Each of the first angle θ1 and the second angle θ2 may range from about 10° to about 80°.

A bottom surface KCLb of the key cell KCL may be lower than a top surface 100t of the substrate 100. The first to fourth crystal planes CRP1 to CRP4 may surround the bottom surface KCLb of the key cell KCL. The first to fourth crystal planes CRP1 to CRP4 according to some implementations may be crystal planes having the same Miller indices. The first to fourth crystal planes CRP1 to CRP4 according to some implementations may have substantially the same silicon atom surface density.

The key patterns KP may be used as an alignment key to perform an ion implantation process IIP on the substrate 100. A logic cell region CER may be a target in the ion implantation process IIP. The ion implantation process IIP may be performed at least twice on the logic cell region CER. In this step, the key patterns KP on the key region KER may be used as an alignment key and/or an overlay key.

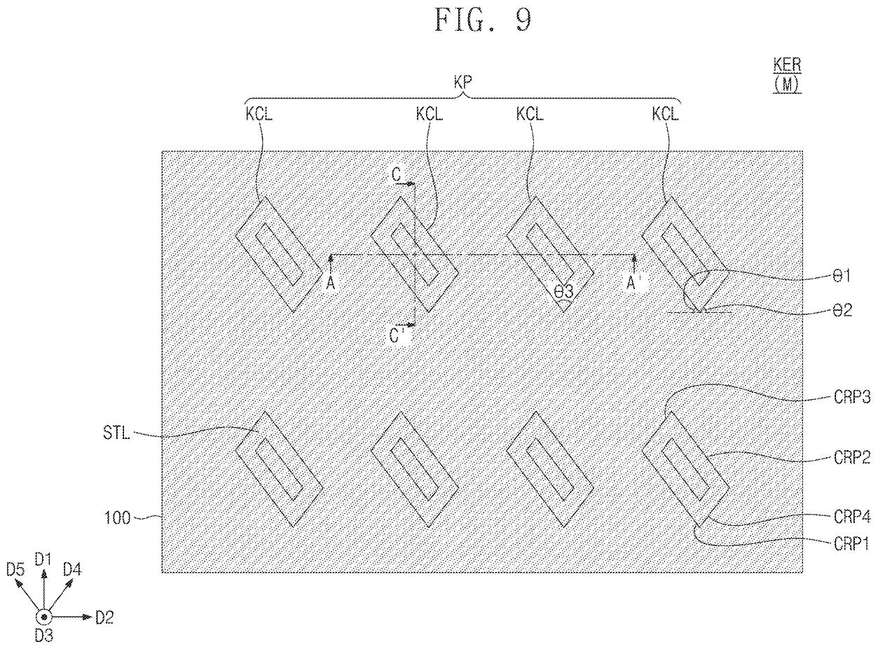

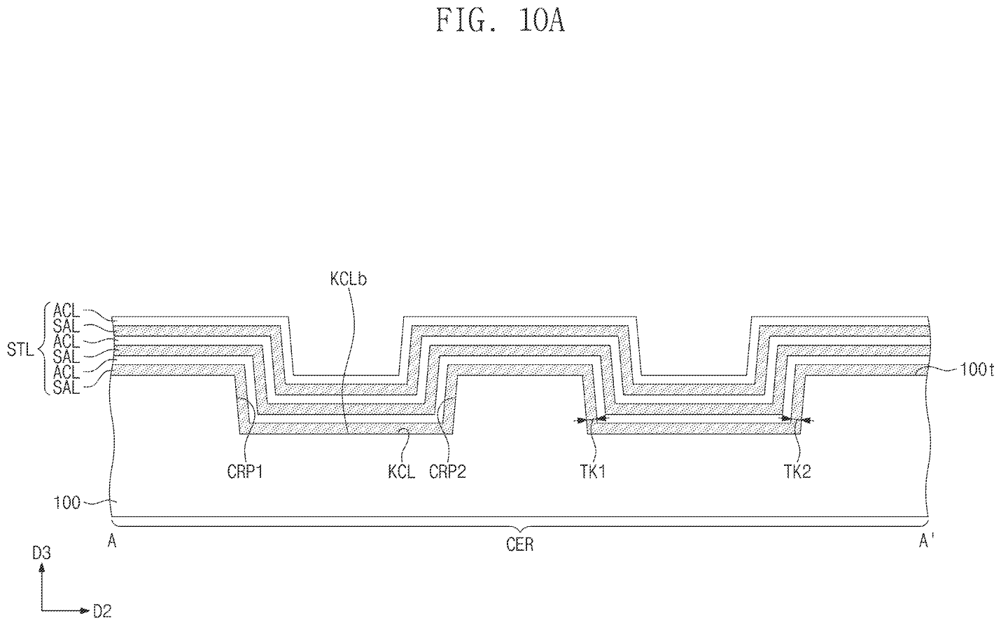

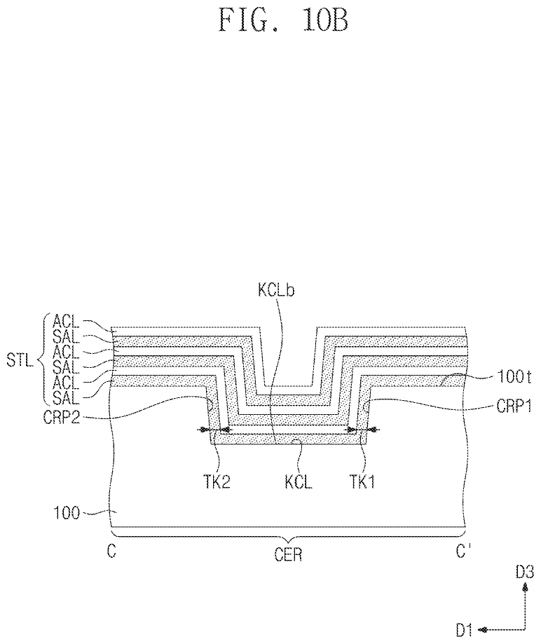

Referring to FIGS. 9, 10A, and 10B, active layers ACL and sacrificial layers SAL may be alternately formed on the substrate 100. The active layers ACL may include one of silicon (Si), germanium (Ge), and silicon-germanium (SiGe), and the sacrificial layers SAL may include another of silicon (Si), germanium (Ge), and silicon-germanium (SiGe). The active layers ACL and the sacrificial layers SAL may constitute a stack structure STL.

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at %.

The stack structure STL may be formed on the top surface 100t of the substrate 100. The stack structure STL may be formed on the bottom surface KCLb and the first to fourth crystal planes CRP1 to CRP4 of the key cell KCL.

A selective epitaxial growth (SEG) process may be employed to form the active layers ACL and the sacrificial layers SAL. A lowermost sacrificial layer SAL of the stack structure STL may directly grow on the first to fourth crystal planes CRP1 to CRP4.

As discussed above, the first to fourth crystal planes CRP1 to CRP4 may have substantially the same silicon atom surface density. Therefore, the stack structure STL on the first to fourth crystal planes CRP1 to CRP4 may grow to have a uniform thickness. As the first to fourth crystal planes CRP1 to CRP4 have the same silicon atom surface density, the first to fourth crystal planes CRP1 to CRP4 may have the same growth rate of a semiconductor layer, with the result the first to fourth crystal planes CRP1 to CRP4 may have a uniform thickness.

For example, the sacrificial layer SAL on the first crystal plane CRP1 may be formed to have a first thickness TK1, and the sacrificial layer SAL on the second crystal plane CRP2 may be formed to have a second thickness TK2. The first thickness TK1 and the second thickness TK2 may be substantially the same as each other.

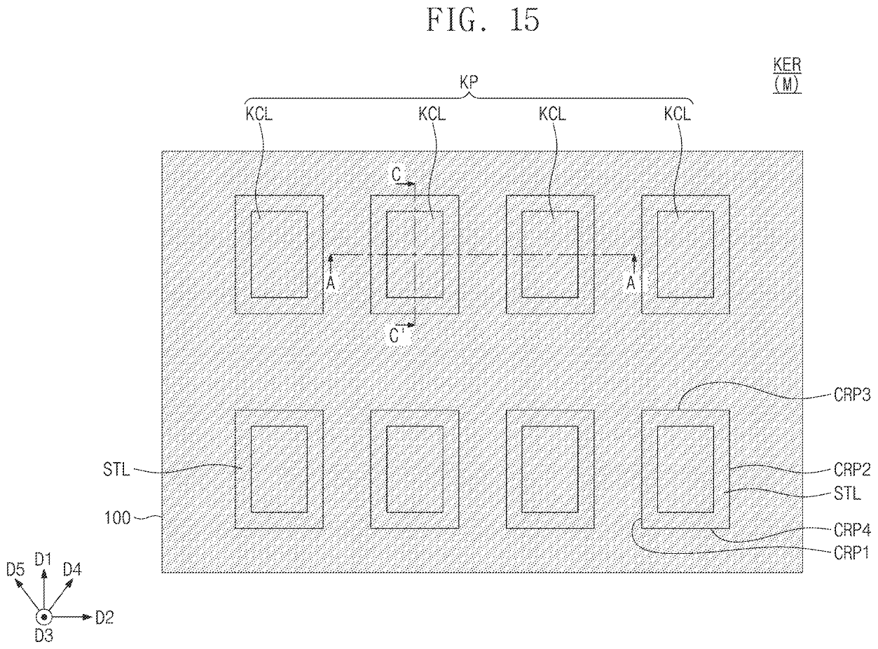

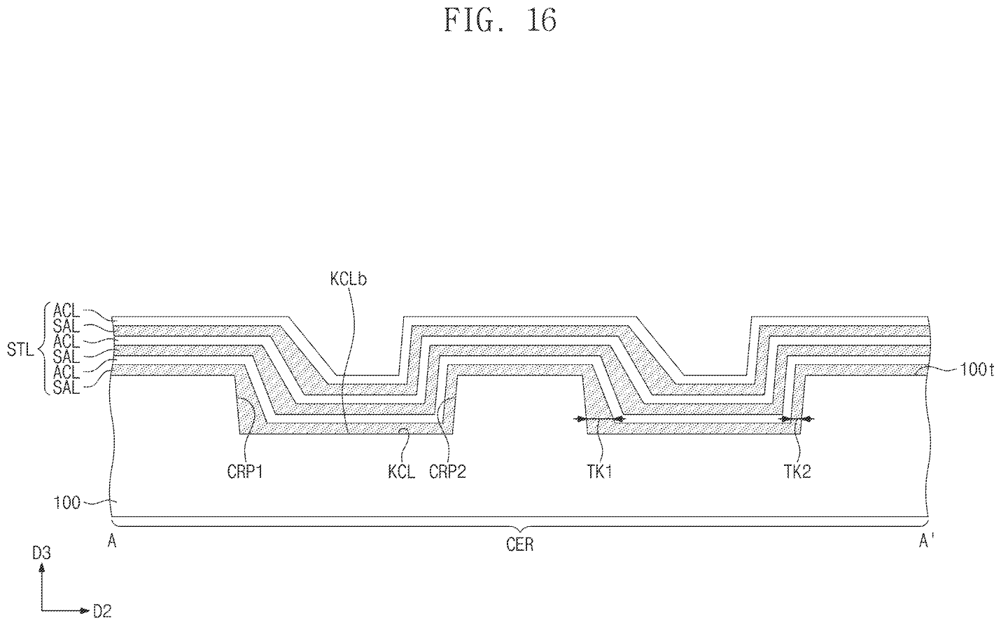

FIG. 15 illustrates a plan view showing another example of a method of fabricating a semiconductor device. FIG. 16 illustrates an example of a cross-sectional view taken along line A-A′ of FIG. 15. Referring to FIGS. 15 and 16, each of key cells KCL according to a comparative example may have a rectangular shape. The key cell KCL may have first and second crystal planes CRP1 and CRP2 that are parallel to a first direction D1. The key cell KCL may have third and fourth crystal planes CRP3 and CRP4 that are parallel to a second direction D2.

When a substrate 100 is a (110) wafer or a (111) wafer, the first to fourth crystal planes CRP1 to CRP4 may have their silicon atom surface densities that are different from each other. For example, the silicon atom surface density of the first crystal plane CRP1 may be different from that of the second crystal plane CRP2.

As the first and second crystal planes CRP1 and CRP2 have different silicon atom surface densities from each other, a stack structure STL on the first crystal plane CRP1 and a stack structure STL on the second crystal plane CRP2 may grow to have different thicknesses from each other. This may be caused by the fact that the first and second crystal planes CRP1 and CRP2 have different growth rates of semiconductor layers.

For example, a sacrificial layer SAL on the first crystal plane CRP1 may be formed to have a first thickness TK1, and a sacrificial layer SAL on the second crystal plane CRP2 may be formed to have a second thickness TK2. The first thickness TK1 may be greater than the second thickness TK2. In this case, a growth rate of the sacrificial layer SAL on the first crystal plane CRP1 may be greater than that of the sacrificial layer SAL on the second crystal plane CRP2.

As illustrated in the comparative example, when the crystal planes CRP1 to CRP4 of the key cell KCL have different silicon atom surface densities from each other, the stack structure STL on the key cell KCL may be formed to have an asymmetric structure as shown in FIG. 16. The asymmetric structure of the stack structure STL may reduce a performance of alignment and overlay measurement of the key pattern KP. This may cause serious process defects.

Referring back to FIGS. 9, 10A, and 10B, the stack structure STL according to some implementations may be formed to have a symmetric structure on the key cell KCL. For example, even when the substrate 100 is a (110) wafer or a (111) wafer, the first to fourth crystal planes CRP1 to CRP4 may be formed in oblique directions (or, the fourth direction D4 and the fifth direction D5), and thus may be controlled to have the same silicon atom surface density. As a result, the key pattern KP may provide improved performance of alignment and overlay measurement.

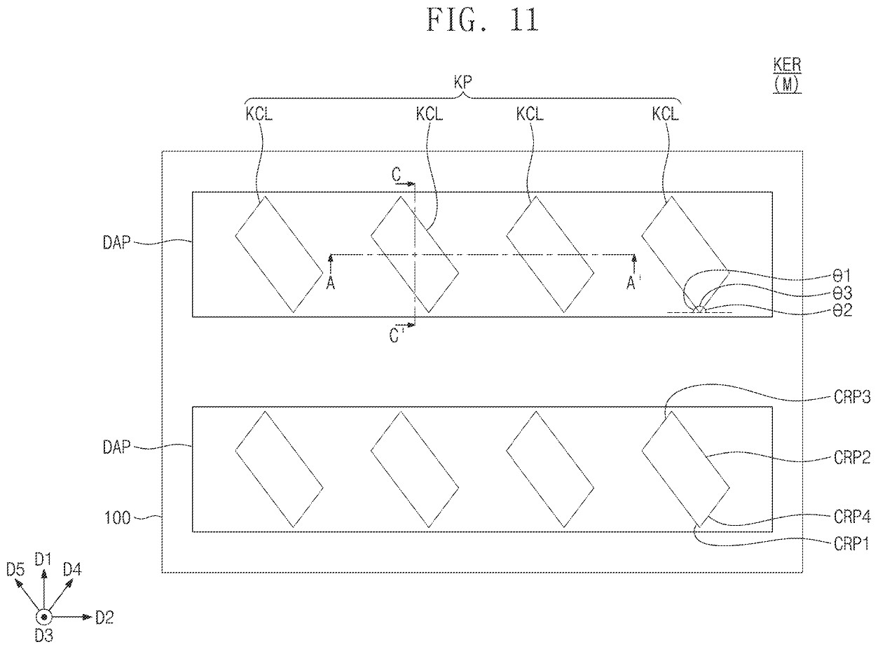

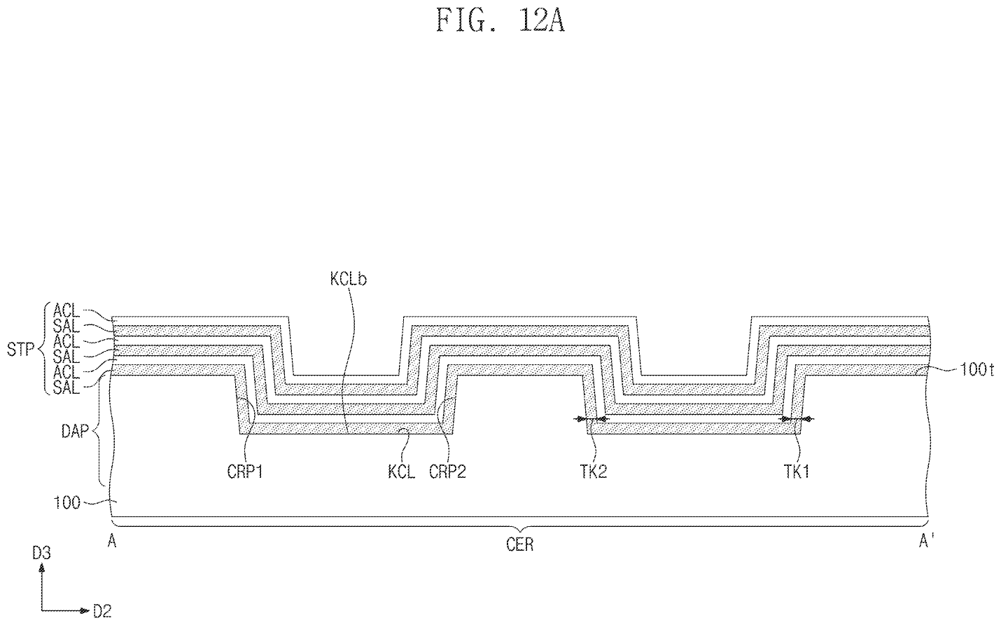

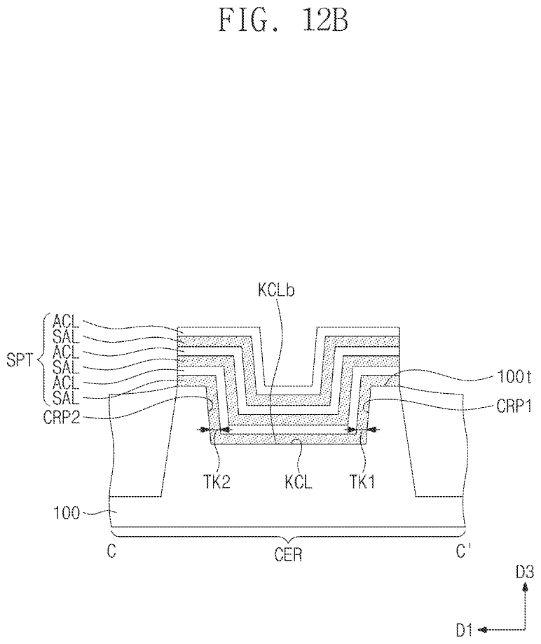

Referring to FIGS. 11, 12A, and 12B, mask patterns may be formed on the key region KER of the substrate 100. The mask patterns may have a linear or bar shape that extends in the second direction D2.

The mask patterns may be used as an etching mask to perform a patterning process to form dummy active patterns DAP. During the patterning process, the stack structure STL may also be patterned to form a stack pattern STP. The patterning process may form a trench TR between the dummy active patterns DAP.

The stack pattern STP may be formed on each of the dummy active patterns DAP. The stack pattern STP may vertically overlap the dummy active pattern DAP. The stack pattern STP may include the active layers ACL and the sacrificial layers SAL that are alternately stacked.

When the dummy active patterns DAP are formed, first and second active patterns AP1 and AP2 may be formed at the same time on the logic cell region CER discussed with reference to FIGS. 2 and 3A to 3D.

The key patterns KP may be used as an alignment key in a photolithography process for forming the first and second active patterns AP1 and AP2. In an example, the photolithography process may be an extreme ultraviolet (EUV) lithography process. After the formation of the first and second active patterns AP1 and AP2 and the dummy active patterns DAP, an overlay between the key patterns KP and the dummy active patterns DAP may be measured to ascertain whether the first and second active patterns AP1 and AP2 are exactly formed.

A device isolation layer ST may be formed to fill the trench TR. For example, a dielectric layer may be formed on an entire surface of the substrate 100, covering the dummy active patterns DAP and the stack patterns STP. The dielectric layer may be recessed until the stack patterns STP are exposed, and thus the device isolation layer ST may be formed.

The device isolation layer ST may include a dielectric material, such as a silicon oxide layer. The stack patterns STP may be exposed upwardly from the device isolation layer ST. For example, the stack patterns STP may vertically protrude upwards from the device isolation layer ST.

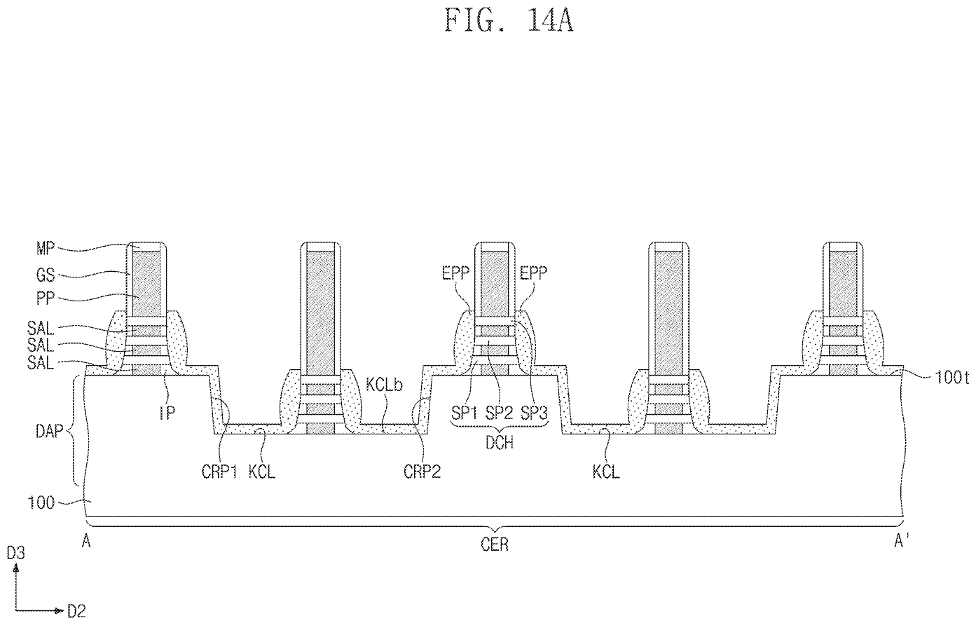

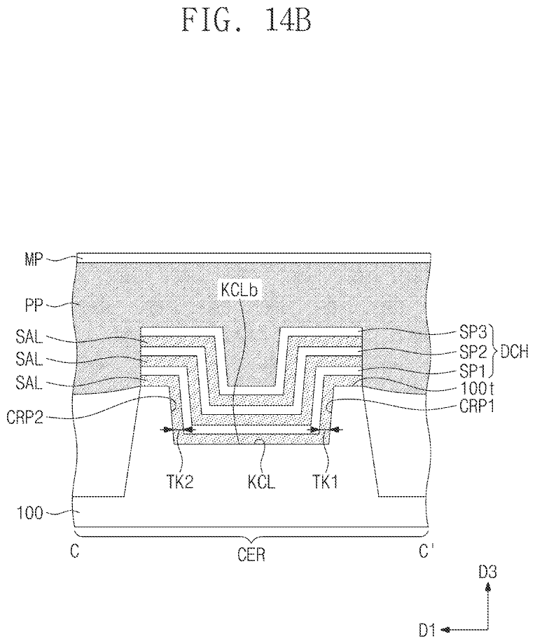

Referring to FIGS. 13, 14A, and 14B, sacrificial patterns PP may be formed on the substrate 100 to run across the stack patterns STP. The sacrificial patterns PP may be formed to each have a linear shape that extends in a first direction D1.

For example, the formation of the sacrificial patterns PP may include forming a sacrificial layer on the entire surface of the substrate 100, forming hardmask patterns MP on the sacrificial layer, and using the hardmask patterns MP as an etching mask to pattern the sacrificial layer. The sacrificial layer may include a polysilicon layer.

In some implementations, the process for forming the hardmask patterns MP may include a lithography process that uses an extreme ultraviolet (EUV) radiation. In this description, the EUV may mean an ultraviolet ray having a wavelength of about 4 nm to about 124 nm, narrowly about 4 nm to about 20 nm, and more narrowly about 13.5 nm. The EUV may denote light whose energy is in the range of about 6.21 eV to about 124 eV, for example, of about 90 eV to about 95 eV.

The lithography process that uses the EUV may include exposure and development processes that use the EUV irradiated onto a photoresist layer. For example, the photoresist layer may be an organic photoresist that contains an organic polymer such as polyhydroxystyrene.

The organic photoresist may further include a photosensitive compound sensitive to the EUV. The organic photoresist may additionally include a material whose EUV absorption coefficient is high, for example, an organometallic material, an iodine-containing material, or a fluorine-containing material. For another example, the photoresist layer may be an inorganic photoresist that contains an inorganic material, such as tin oxide.

The photoresist layer may be formed to have a relatively small thickness. The photoresist layer exposed to the EUV may be developed to form photoresist patterns. When viewed in plan, the photoresist patterns may have a linear shape that extends in one direction, an island shape, a zigzag shape, a honeycomb shape, or a circular shape, but the concepts are not limited to a particular example.

The photoresist patterns may be used as an etching mask to pattern one or more mask layers that are stacked thereunder to form the hardmask patterns MP. The hardmask patterns MP may be used as an etching mask to pattern a target layer (or the sacrificial layer) to form the sacrificial patterns PP on the substrate 100.

As a comparative example, a multi-patterning technique (MPT) requires the use of two or more photomasks to form fine-pitched patterns on a wafer. In contrast, when an EUV lithography process is performed in some implementations, only a single photomask may be used to form the sacrificial patterns PP.

For example, a value equal to or less than about 45 nm may be given as a minimum pitch between the sacrificial patterns PP formed by an EUV lithography process. Hence, the EUV lithography process used to form the sacrificial patterns PP may be sufficient to form very fine patterns without requiring the multi-patterning technique.

A pair of gate spacers GS may be formed on opposite sidewalls of each of the sacrificial patterns PP. The formation of the gate spacers GS may include conformally forming a gate spacer layer on the entire surface of the substrate 100 and anisotropically etching the gate spacer layer. In an example, the gate spacer GS may be a multiple layer including at least two layers.

The hardmask patterns MP and the gate spacers GS may be used as an etching mask to etch the stack pattern STP. The etching process may continue until the substrate 100 is exposed. Therefore, sidewalls of the sacrificial layers SAL may be exposed. The exposed sacrificial layers SAL may undergo a selective etching process to horizontally recess the sacrificial layers SAL. The recessed sacrificial layers SAL may be filled with a dielectric material to form inner spacers IP.

During the etching process performed on the stack pattern STP, the active layers ACL may be patterned to form first, second, and third semiconductor patterns SP1, SP2, and SP3 that are sequentially stacked. A dummy channel pattern DCH may be constituted by the first, second, and third semiconductor patterns SP1, SP2, and SP3 that are sequentially stacked. First and second channel patterns CH1 and CH2 discussed with reference to FIGS. 2 and 3A to 3D may be simultaneously formed with the dummy channel pattern DCH.

An epitaxial pattern EPP may be formed the substrate 100 and the exposed dummy channel pattern DCH. For example, a selective epitaxial growth (SEG) process may be performed such that a sidewall of the dummy channel pattern DCH may be used as a seed layer to form an epitaxial layer on the sidewall of the dummy channel pattern DCH. The epitaxial layer may grow from a seed, or the exposed substrate 100 and the exposed first, second, and third semiconductor patterns SP1, SP2, and SP3. For example, the SEG process may include chemical vapor deposition (CVD) or molecular beam epitaxy (MBE).

In an example, the epitaxial pattern EPP may include the same semiconductor element (e.g., Si) as that of the substrate 100. While the epitaxial pattern EPP is formed, impurities (e.g., phosphorus, arsenic, or antimony) may be in-situ implanted to allow the epitaxial pattern EPP to have an n-type conductivity. Alternatively, after the epitaxial pattern EPP is formed, impurities may be implanted into the epitaxial pattern EPP. Second source/drain patterns SD2 discussed with reference to FIGS. 2 and 3A to 3D may be simultaneously formed with the epitaxial patterns EPP.

Referring back to FIGS. 5 and 6A to 6C, a first interlayer dielectric layer 110 may be formed to cover the epitaxial patterns EPP, the hardmask patterns MP, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be employed to planarize the first interlayer dielectric layer 110. The hardmask patterns MP may all be removed during the planarization process. As a result, the first interlayer dielectric layer 110 may have a top surface coplanar with those of the sacrificial patterns PP and those of the gate spacers GS.

The exposed sacrificial patterns PP may be selectively removed. The removal of the sacrificial patterns PP may form an outer region that exposes the dummy channel patterns DCH. The removal of the sacrificial patterns PP may include performing a wet etching process using an etchant that selectively etches polysilicon.

The sacrificial layers SAL exposed through the outer region may be selectively removed to form inner regions. For example, an etching process that selectively etches the sacrificial layers SAL may be performed such that only the sacrificial layers SAL may be removed while leaving the first, second, and third semiconductor patterns SP1, SP2, and SP3. The etching process may have a high etch rate with respect to silicon-germanium having a relatively high germanium concentration. For example, the etching process may have a high etch rate with respect to silicon-germanium whose germanium concentration is greater than about 10 at %.

The sacrificial layers SAL may be selectively removed to leave the first, second, and third semiconductor patterns SP1, SP2, and SP3 that are stacked on the dummy active pattern DAP. Regions where the sacrificial layers SAL are removed may be formed into first to third inner regions.

A gate dielectric layer GI may be formed on the exposed first, second, and third semiconductor patterns SP1, SP2, and SP3. The gate dielectric layer GI may be formed to surround each of the first, second, and third semiconductor patterns SP1, SP2, and SP3. For example, the gate dielectric layer GI may include an interfacial layer and a high-k dielectric material that are sequentially stacked.

A DGE may be formed on the gate dielectric layer GI. The DGE may include first, second, and third inner electrodes PO1, PO2, and PO3 that are respectively formed in the first, second, and third inner regions, and may also include an outer electrode PO4 formed in the outer region. The DGE may be recessed to have a reduced height.

A gate capping pattern GP may be formed on the recessed DGE. Gate electrodes GE discussed with reference to FIGS. 2 and 3A to 3D may be simultaneously formed with the dummy gate electrodes DGE.

A second interlayer dielectric layer 120 may be formed on the first interlayer dielectric layer 110. The second interlayer dielectric layer 120 may include a silicon oxide layer. Dummy active contacts DAC may be formed to penetrate the second interlayer dielectric layer 120 and the first interlayer dielectric layer 110. Active contacts AC discussed with reference to FIGS. 2 and 3A to 3D may be simultaneously formed with the dummy active contacts DAC.

A third interlayer dielectric layer 130 may be formed on the second interlayer dielectric layer 120. A first metal layer M1, which is discussed above with reference to FIGS. 2 and 3A to 3D, may be formed in the third interlayer dielectric layer 130. A fourth interlayer dielectric layer 140 may be formed on the third interlayer dielectric layer 130. A second metal layer M2, which is discussed above with reference to FIGS. 2 and 3A to 3D, may be formed in the fourth interlayer dielectric layer 140.

The following will describe various implementations. In the implementation that follows, a detailed description of technical features repetitive to those discussed above with reference to FIGS. 5 and 6A to 6C will be omitted, and a difference thereof will be discussed in detail.

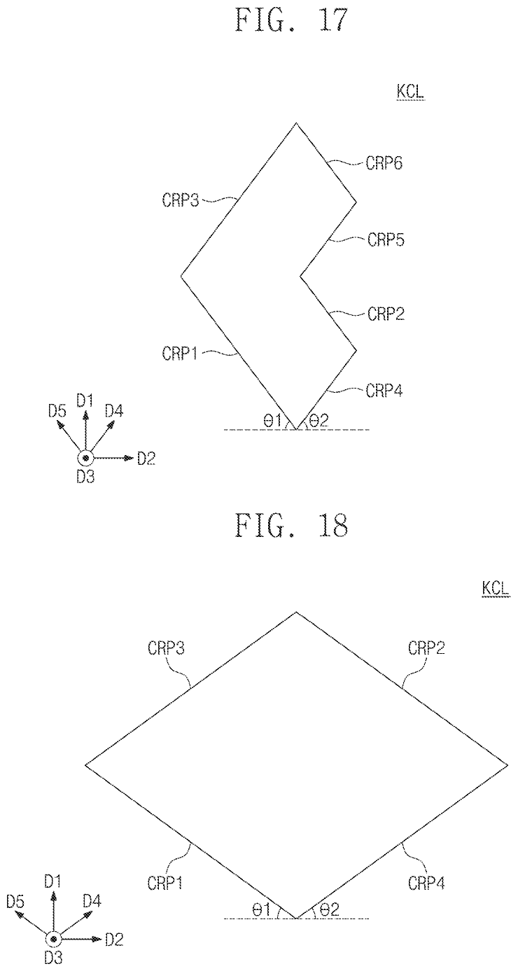

FIGS. 17 and 18 illustrate plan views showing an example of a key cell. Referring to FIG. 17, each of the key cells KCL included in the key pattern KP may have a polygonal shape. The key cell KCL may include first to sixth crystal planes CRP1 to CRP6.

The first, second, and sixth crystal planes CRP1, CRP2, and CRP6 may be parallel to the fifth direction D5. The third, fourth, and fifth crystal planes CRP3, CRP4, and CRP5 may be parallel to the fourth direction D4. For example, inner lateral surfaces that constitute the key cell KCL may be parallel to the fourth direction D4 or the fifth direction D5. Thus, the crystal planes CRP1 to CRP6 of the key cell KCL may have substantially the same silicon atom surface density.

Referring to FIG. 18, each of the key cells KCL included in the key pattern KP may have a rhombic shape. The key cell KCL may include first to fourth crystal planes CRP1 to CRP4. The first and second crystal planes CRP1 and CRP2 may be parallel to the fifth direction D5. The third and fourth crystal planes CRP3 and CRP4 may be parallel to the fourth direction D4. The fifth direction D5 may have a first angle θ1 with respect to the second direction D2. The fourth direction D4 may have a second angle θ2 with respect to the second direction D2. The first angle θ1 and the second angle θ2 may be substantially the same as each other.

The first and second angles θ1 and θ2 may be less than the first and second angles θ1 and θ2 discussed above in FIG. 5. For example, the crystal planes CRP1 to CRP4 of the key cell KCL may have their Miller indices different from those of the crystal planes CRP1 to CRP4 of the key cell KCL discussed above in FIG. 5. The crystal planes CRP1 to CRP4 of the key cell KCL may have their silicon atom surface densities different from those of the crystal planes CRP1 to CRP4 of the key cell KCL discussed above in FIG. 5.

In some implementations, inner lateral surfaces of a key cell included in a key pattern may have substantially the same silicon atom surface density. In this configuration, an epitaxial semiconductor layer may grow to have a uniform thickness on the key cell, and thus there may be an improvement in performance of alignment and overlay measurement. In conclusion, the key pattern may prevent process defects of semiconductor fabrication process and may increase reliability of devices.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Although some implementations have been discussed with reference to accompanying figures, it will be understood that various changes in form and details may be made therein without departing from the spirit and scope of concepts disclosed herein. It therefore will be understood that the embodiments described above are just illustrative but not limitative in all aspects.

1. A semiconductor device, comprising:
a substrate including a logic cell region and a key region;
a dummy active pattern on the key region; and
a key pattern in the dummy active pattern,
wherein the key pattern includes a key cell that is recessed at an upper portion of the substrate,
wherein the key cell includes:
a bottom surface lower than a top surface of the dummy active pattern; and
a plurality of inner lateral surfaces that surround the bottom surface,
wherein the inner lateral surfaces include a first inner lateral surface and a second inner lateral surface opposite to the first inner lateral surface, and
wherein a ratio of a silicon atom surface density of the second inner lateral surface to a silicon atom surface density of the first inner lateral surface is in a range of about 0.9 to about 1.1.

2. The semiconductor device of claim 1, wherein
the dummy active pattern includes a plurality of first dummy active subpatterns arranged along a first direction,
the dummy active pattern includes a plurality of second dummy active subpatterns extend along a second direction that intersects the first direction,
the plurality of inner lateral surfaces include a third inner lateral surface that connects the first inner lateral surface to the second inner lateral surface,
each of the first inner lateral surface and the second inner lateral surface is parallel to a third direction that intersects both the first direction and the second direction, and
the third inner lateral surface is parallel to a fourth direction that is symmetric to the third direction about the first direction.

3. The semiconductor device of claim 2, wherein
the third direction has a first angle with respect to the second direction,
the fourth direction has a second angle with respect to the second direction, and
the first angle and the second angle are substantially same.

4. The semiconductor device of claim 3, wherein each of the first angle and the second angle is in a range of about 10° to about 80°.

5. The semiconductor device of claim 1, comprising:
a dummy channel pattern on the dummy active pattern, wherein the dummy channel pattern includes a plurality of semiconductor patterns that are stacked and spaced apart from each other; and
a dummy gate electrode on the dummy channel pattern,
wherein the dummy gate electrode surrounds a top surface, a bottom surface, and opposite sidewalls of each of the plurality of semiconductor patterns.

6. The semiconductor device of claim 5, comprising a gate dielectric layer between the dummy gate electrode and the dummy channel pattern,
wherein the gate dielectric layer directly covers the top surface, the bottom surface, and the opposite sidewalls of each of the plurality of semiconductor patterns.

7. The semiconductor device of claim 5, comprising an epitaxial pattern connected to the dummy channel pattern,
wherein the epitaxial pattern covers the bottom surface of the key cell and the inner lateral surfaces of the key cell.

8. The semiconductor device of claim 1, wherein, when viewed in plan, the key cell has a rhombic shape or a parallelogram shape.

9. The semiconductor device of claim 1, comprising:
an active pattern on the logic cell region;
a channel pattern on the active pattern;
a source/drain pattern connected to the channel pattern; and
a gate electrode on the channel pattern.

10. The semiconductor device of claim 9, wherein
the channel pattern includes a plurality of semiconductor patterns that are stacked and spaced apart from each other, and
the gate electrode surrounds a top surface, a bottom surface, and opposite sidewalls of each of the plurality of semiconductor patterns.

11. A semiconductor device, comprising:
a substrate that includes a key region;
a dummy active pattern on the key region; and
a key pattern in the dummy active pattern,
wherein the key pattern includes a key cell that is recessed at an upper portion of the substrate,
wherein the key cell includes:
a bottom surface lower than a top surface of the dummy active pattern; and
a plurality of inner lateral surfaces that surround the bottom surface,
wherein the dummy active pattern includes a plurality of first dummy active subpatterns arranged along a first direction,
wherein the dummy active pattern includes a plurality of second dummy active subpatterns extend along a second direction that intersects the first direction,
wherein the inner lateral surfaces include first, second, and third inner lateral surfaces,
wherein the first inner lateral surface is opposite to the second inner lateral surface,
wherein the third inner lateral surface connects the first inner lateral surface to the second inner lateral surface,
wherein each of the first and second inner lateral surfaces is parallel to a third direction that intersects both the first direction and the second direction, and
wherein the third inner lateral surface is parallel to a fourth direction that is symmetric to the third direction about the first direction.

12. The semiconductor device of claim 11, comprising a device isolation layer that fills a trench between adjacent dummy active subpatterns.

13. The semiconductor device of claim 11, wherein
the third direction has a first angle with respect to the second direction,
the fourth direction has a second angle with respect to the second direction, and
the first angle and the second angle are substantially same.

14. The semiconductor device of claim 13, wherein each of the first angle and the second angle is in a range of about 10° to about 80°.

15. The semiconductor device of claim 11, wherein, when viewed in plan, the key cell has a rhombic shape or a parallelogram shape.

16. A semiconductor device, comprising:
a substrate that includes a key region;
a dummy active pattern on the key region; and
a key pattern in the dummy active pattern,
wherein the key pattern includes a plurality of key cells each of which is recessed at an upper portion of the substrate,
wherein the plurality of key cells are arranged at a regular interval along the dummy active pattern,
wherein each of the plurality of key cells includes:
a bottom surface lower than a top surface of the dummy active pattern; and
a plurality of inner lateral surfaces that surround the bottom surface,
wherein the plurality of key cells have a same polygonal shape when viewed in plan.

17. The semiconductor device of claim 16, wherein
the inner lateral surfaces include a first inner lateral surface and a second inner lateral surface opposite to the first inner lateral surface, and
a ratio of a silicon atom surface density of the second inner lateral surface to a silicon atom surface density of the first inner lateral surface is in a range of about 0.9 to about 1.1.

18. The semiconductor device of claim 16, wherein
the inner lateral surfaces include a first inner lateral surface and a second inner lateral surface adjacent to the first inner lateral surface, and
an angle between the first inner lateral surface and the second inner lateral surface is in a range of about 10° to about 80°.

19. The semiconductor device of claim 16, wherein, when viewed in plan, each of the plurality of key cells has a rhombic shape or a parallelogram shape.

20. The semiconductor device of claim 16, further comprising:
a dummy channel pattern on the dummy active pattern, wherein the dummy channel pattern includes a plurality of semiconductor patterns that are stacked and spaced apart from each other; and
a dummy gate electrode on the dummy channel pattern,
wherein the dummy gate electrode surrounds a top surface, a bottom surface, and opposite sidewalls of each of the plurality of semiconductor patterns.

21.-25. (canceled)
